(19) United States
(12) Patent Application Publication
(10) Pub. No.: US 2009/0300466 A1
(43) Pub. Date: Dec. 3, 2009

(54) ERROR CORRECTION METHOD AND ERROR CORRECTION CIRCUIT

(75) Inventor: Noritsugu Yoshimura, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/346,548

(22) Filed: Dec. 30, 2008

(30) Foreign Application Priority Data
May 28, 2008 (JP) 2008-139342

(51) Int. Cl. G11C 29/04; G06F 11/07

(52) U.S. Cl. 714/769; 714/E11.021

(57) ABSTRACT

In an error correction method, an error correction of data can be completed readily in a short period of time. In this method, actual data are written together with additional data to a magnetic disk having sectors. The actual data have a first length. The additional data are produced from source data. The source data are formed by predetermined data or the actual data. The sectors of the magnetic disk have a read/write unit of a second length that is longer than the first length. One of the sectors to which actual data to be read have been written is specified, and actual data and additional data are read from the specified sector. The read additional data are verified with the source data. A first error correction is performed on the read additional data based on a result of the verification.

### CROSS-REFERENCE TO RELATED APPLICATION

This application is based upon and claims the benefit of priority of the prior Japanese Patent Application No. 2008-139342, filed on May 28, 2008, the entire contents of which are incorporated herein by reference.

### FIELD

The present invention relates to an error correction method, an error correction circuit, and a magnetic disk device, and more particularly to an error correction method and an error correction circuit used for reading data from a sector having a length larger than that of actual data inputted from a host, and a magnetic disk device having such an error correction circuit.

### BACKGROUND

Generally, a conventional magnetic disk device adds information such as a cyclic redundancy check (CRC) or an error correcting code (ECC) to data acquired from a host computer or the like and then writes those data to a magnetic disk. In such a magnetic disk device, however, the direction of magnetization of a magnetic material applied on a magnetic disk may change due to thermal fluctuation or the like in the course of time. Therefore, data may be unable to be read correctly from the magnetic disk if a certain period of time has elapsed since the data were written to the magnetic disk.

Accordingly, in recent years, a rewrite process of rereading written data from a magnetic disk and then rewriting the read data to the magnetic disk at certain intervals has been used to prevent the written data from being unable to be read.

Meanwhile, for example, Japanese laid-open patent publication No. 2004-14090 discloses changing parameters for a data reading circuit depending upon changes of the temperature of a magnetic disk device in order to efficiently read data written to a magnetic disk.

Furthermore, there has recently been proposed a method of estimating the location of an error in data before an ECC correction.

However, in the case where the location of an error is estimated for correction, many retrials may be required to complete correction of an error in data. Additionally, failure in estimation of the location of an error may result in abandonment of correction of the error.

Furthermore, in some magnetic disk devices, the sector length of a host device is different from that of a magnetic disk (long sector length). In such cases, some dummy data should be written to a space area in one sector of the magnetic disk to which input data (actual data) have not been written. If an error has occurred in such dummy data, error correction may require more time because of the effect of the error in the dummy data. In some cases, even if no error has occurred in actual data, the actual data cannot be read because of the error in the dummy data.

### SUMMARY

According to a first aspect of the present invention, there is provided an error correction method capable of completing an error correction of data readily in a short period of time. In this method, actual data are written together with additional data to a magnetic disk having sectors. The actual data have a first length. The additional data are produced from source data. The sectors of the magnetic disk have a read/write unit of a second length that is longer than the first length. One of the sectors to which actual data to be read have been written is specified, and actual data and additional data are read from the specified sector. The read additional data are verified with the source data. A first error correction is performed on the read additional data based on a result of the verification.

According to a second aspect of the present invention, there is provided an error correction circuit capable of completing an error correction of data readily in a short period of time. The error correction circuit includes a writing unit operable to write actual data together with additional data to a magnetic disk having sectors. The actual data have a first length. The additional data are produced from source data. The sectors have a read/write unit of a second length that is longer than the first length. The error correction circuit also includes a reading unit operable to specify one of the sectors to which actual data to be read have been written and to read actual data and additional data from the specified sector. The error correction circuit includes a verification unit operable to verify the read additional data with the source data and a correction unit operable to perform a first error correction on the read additional data based on a result of the verification.

According to a third aspect of the present invention, there is provided a magnetic disk device capable of improving the accuracy and speed of reading data from a magnetic disk. The magnetic disk device includes a magnetic disk having sectors and a writing unit operable to write actual data together with additional data to the magnetic disk. The actual data have a first length. The additional data are produced from source data. The sectors have a read/write unit of a second length that is longer than the first length. The error correction circuit also includes a reading unit operable to specify one of the sectors to which actual data to be read have been written and to read actual data and additional data from the specified sector. The error correction circuit includes a verification unit operable to verify the read additional data with the source data and a correction unit operable to perform a first error correction on the read additional data based on a result of the verification.

### BRIEF DESCRIPTION OF THE DRAWINGS

FIG. 1 is a plan view showing an internal structure of a hard disk drive (HDD) according to an embodiment of the present invention;

FIG. 2 is a block diagram showing components of the HDD shown in FIG. 1;

FIG. 3 is a diagram showing an example of data recorded to one sector of a magnetic disk in the HDD shown in FIG. 1;

FIG. 4 is a flow chart showing a sequence of an error correction performed when data are read from the magnetic disk;

FIG. 5 is a flow chart showing a process of a subroutine S28 shown in FIG. 4;

FIG. 6 is a block diagram showing a process of transferring and processing actual data from a host interface controller and a read channel in the HDD shown in FIG. 2;

FIGS. 7A to 7C are diagrams explanatory of an HRRLL conversion;

FIG. 8 is a diagram showing an example in which the length of code words is reduced;

FIGS. 9A and 9B are diagrams showing examples in which surplus bits are appended to each set of data;

FIG. 10 is a diagram showing an example in which dummy data are not subjected to an RLL conversion;

FIG. 11 is a block diagram showing an arrangement of an MPU in the HDD for the example shown in FIG. 10;

FIG. 12 is a diagram showing an example in which a CRC portion is not subjected to an RLL conversion;

FIG. 13 is a block diagram showing an arrangement of the MPU in the HDD for the example shown in FIG. 12;

FIG. 14 is a diagram showing a variation of the example shown in FIG. 12;

FIG. 15 is a diagram showing a data structure in an example in which duplicate data of actual data are used instead of dummy data;

FIG. 16 is a flow chart showing a sequence of an error correction performed when data shown in FIG. 15 are read from the magnetic disk; and

FIG. 17 is a block diagram showing a variation of addition of dummy data to actual data.

### DESCRIPTION OF EMBODIMENTS

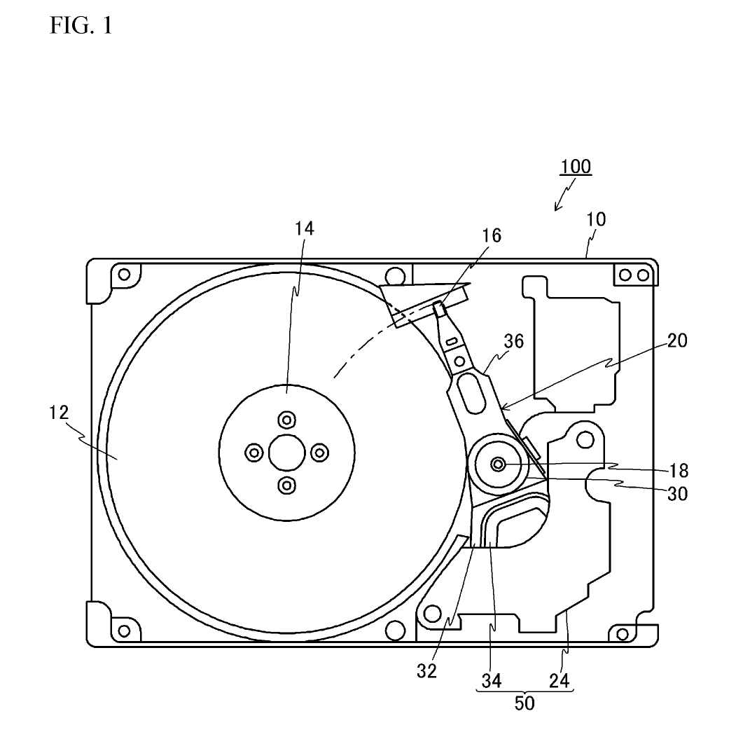

An embodiment of a magnetic disk device suitable for use in an error correction method according to the present invention will be described in detail with reference to FIGS. 1-14.

FIG. 1 shows an internal structure of a hard disk drive (HDD) 100 as a magnetic disk device according to an embodiment of the present invention. As shown in FIG. 1, the HDD 100 includes a box-shaped frame 10, a magnetic disk 12 housed in a space (receptacle space) inside of the frame 10, a spindle motor 14, and a head stack assembly (HSA) 20. Although the frame 10 is practically formed by a base and a top cover, FIG. 1 only shows the base for the purpose of illustration.

The magnetic disk 12 has front and rear faces serving as recording surfaces. The magnetic disk 12 is rotated about the rotation axis at a high speed of, for example, 4,200 rpm to 15,000 rpm by the spindle motor 14. A plurality of magnetic disks may be arranged in a direction perpendicular to the paper of FIG. 1.

The HSA 20 includes a cylindrical housing portion 30, a fork portion 32 fixed to the housing portion 30, a coil 34 supported in the fork portion 32, a carriage arm fixed to the housing portion 30, and a head slider 16 supported by the carriage arm 36. An additional carriage arm and an additional head slider are provided on a rear side of the magnetic disk 12 in addition to the illustrated carriage arm 36 and head slider 16, which are provided on a front side of the magnetic disk 12. The front-side carriage arm and head slider and the rear-side carriage arm and head slider are positioned so as to be symmetrical with respect to the magnetic disk 12.

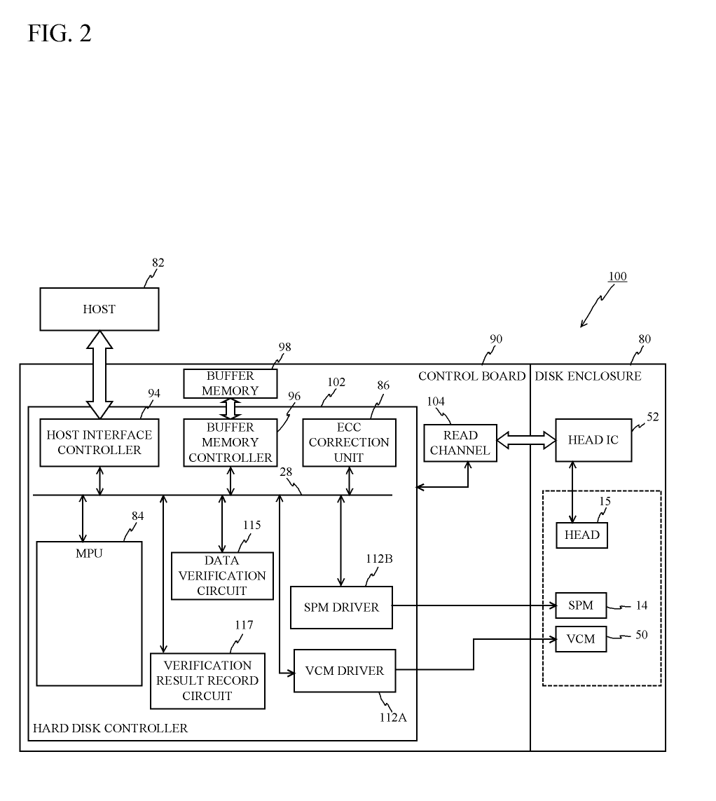

For example, the carriage arm 36 is formed by punching stainless plates or extruding aluminum material. Although not shown in FIG. 1, the head slider 16 has a recording/reproducing head 15 (hereinafter referred to as the head) including a write element and a read element (see FIG. 2). For example, the write element may comprise an element using a magnetic field produced in a thin-film coil pattern to write data to the magnetic disk 12. For example, the read element may comprise a giant magnetoresistance (GMR) element or a tunneling magnetoresistance (TuMR) element, which use changes in resistance of a spin valve film or a tunneling film to read data from the magnetic disk 12.

A bearing member 18 is provided at a central portion of the housing portion 30. The HSA 20 is coupled to the frame 10 by the bearing member 18 so as to be rotatable about the Z-axis. Furthermore, a magnetic pole unit 24 including a permanent magnet is fixed to the frame 10. The coil 34 of the HSA 20 and the magnetic pole unit 24 form a voice coil motor (VCM) 50. The HSA 20 is operable to swing about the bearing member 18 by the voice coil motor 50. In FIG. 1, the swinging movement is indicated by a chain line.

FIG. 2 is a block diagram showing components of the HDD 100. As shown in FIG. 2, the HDD 100 includes a disk enclosure 80 and a control board 90 having an error correction circuit for performing an error correction on data written to the magnetic disk 12.

The disk enclosure 80 includes the aforementioned spindle motor (SPM) 14, voice coil motor (VCM) 50, and head 15, and a head IC 52.

The head IC 52 performs write or read operation in accordance with a write command or a read command from a host 82. In this case, when the HDD 100 has a plurality of heads, the head IC 52 selects one of the heads to perform write or read operation in accordance with a head selection signal based on the command. The head IC 52 includes a write amplifier for a write operation and a preamplifier for a read operation.

The control board 90 includes a hard disk controller 102, a buffer memory 98, and a read channel 104. The hard disk controller 102 includes an MPU 84, a host interface controller 94, a buffer memory controller 96, an ECC correction unit 86 operable to perform an error correction on data read from the magnetic disk 12, a data verification circuit 115 as a verification unit operable to verify the data read from the magnetic disk 12, a verification result record circuit 117, a VCM driver 112A, and an SPM driver 112B. These components of the hard disk controller 102 are connected to a bus line 28.

The ECC correction unit 86 is operable to perform an error correction using EEC on data inputted from the read channel 104. The ECC correction unit 86 is operable to inform the MPU 84 of the normality of data when the data include no errors or when any errors in the data could be corrected. Furthermore, the ECC correction unit 86 is operable to inform the MPU 84 of a data read error when any errors in the data could not be corrected.

The MPU 84 is operable to collectively control the respective components of the hard disk controller 102. The details of the hard disk controller 102 will be described later.

In the present embodiment, the head 15, the head IC 52, the hard disk controller 102, and the read channel 104 form a writing unit operable to write data to the magnetic disk 12 and a reading unit operable to read data from the magnetic disk 12.

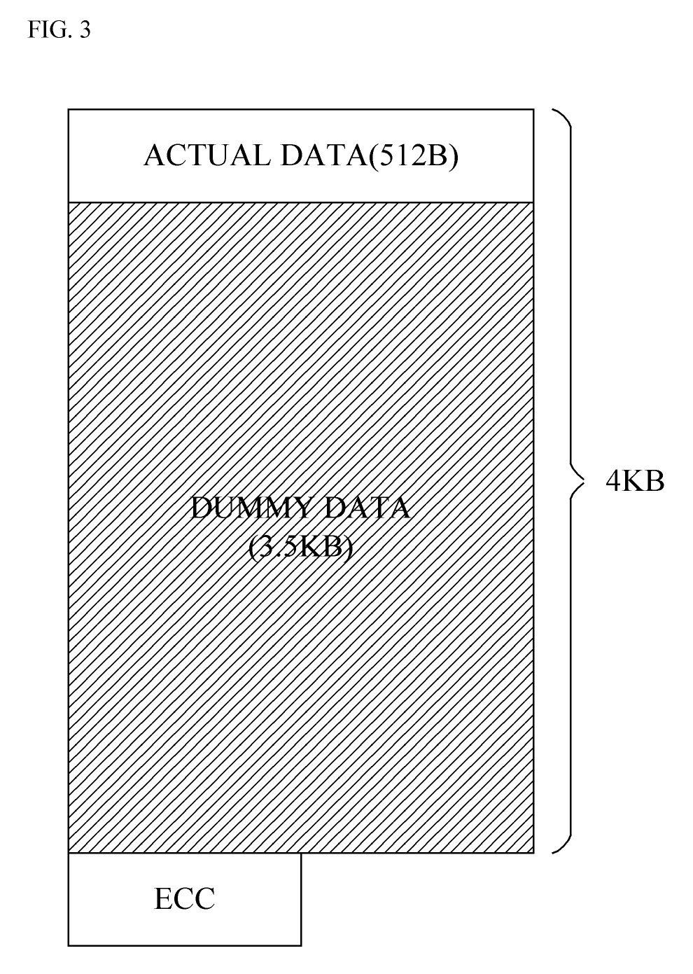

Next, a method of writing data to the magnetic disk 12 in the present embodiment will be described below with reference to FIG. 3. In the present embodiment, data to be written to the magnetic disk 12, which is hereinafter referred to as actual data, are inputted from the host 82. One sector of the data has a length of 512 bytes (first length). As shown in FIG. 3, the magnetic disk 12 uses a long sector format having a read/write unit (one sector) of 4 Kbytes. In view of data transfer, it is desirable that data to be recorded to each sector of the magnetic disk 12 should be uniformized into 4 Kbytes. Therefore, in the present embodiment, dummy data are recorded (written) as additional data to an area in one sector of the magnetic disk 12 other than an area to which the actual data inputted from the host 82 are recorded. For example, the dummy data are produced from predetermined source data in which all data elements are zero.

In this case, when actual data are inputted from the host 82, they are stored in the buffer memory 98. In the buffer memory 98, dummy data are appended to the actual data so as to generate data having 4-Kbyte sectors. The write data including those actual data and dummy data are transferred to the head IC 52 via the read channel 104 and written to a specific sector of the magnetic disk 12 by the head 15 in the same sequence as a usual write operation. The source data for the dummy data are stored in the buffer memory 98. In this example, all data elements of the source data are zero. A data read error may occur when written dummy data are read from the magnetic disk 12. In such a case, the dummy data read from the magnetic disk 12 include data elements other than zero. Thus, all data elements of the dummy data read from the magnetic disk 12 may not necessarily be zero.

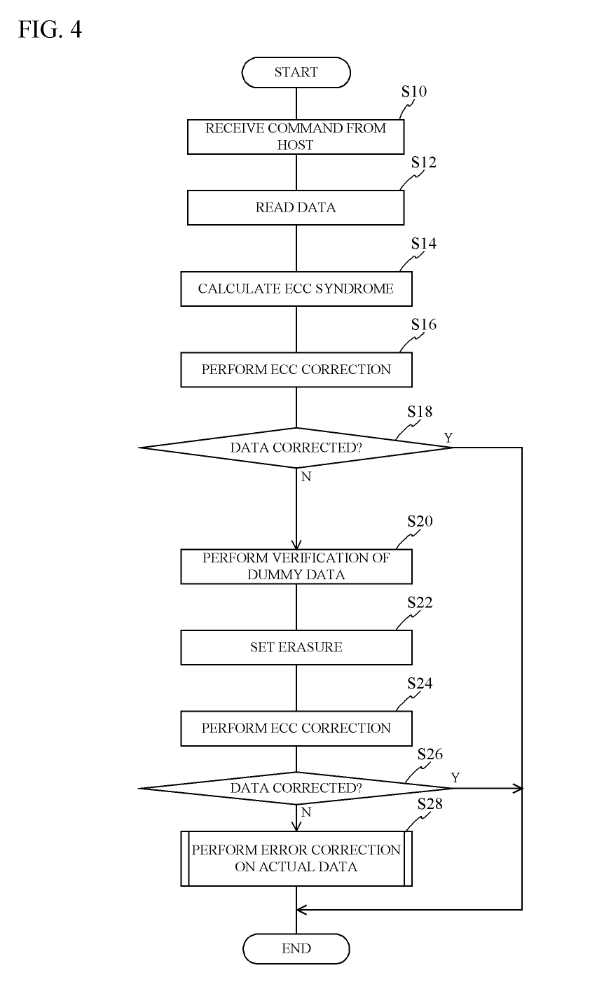

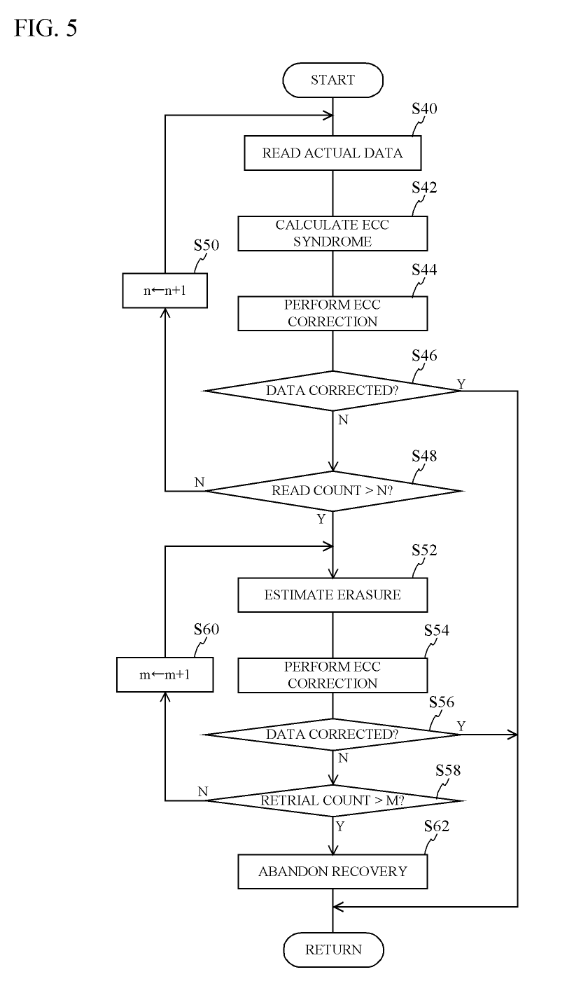

Next, a sequence of an error correction performed at the time of reading data in the present embodiment will be described with reference to flow charts shown in FIGS. 4 and 5.

In Step S10 of FIG. 4, when the MPU 84 receives a command for reading data (read command) from the host 82 via the host interface controller 94, then Step S12 proceeds. In Step S12, the MPU 84 decodes the read command and executes a read operation of data from a sector specified by the command.

Based on the decoded command, the MPU 84 controls the VCM driver 112A to position the head 15 (the head selected by the head IC 52 in the case where a plurality of heads are provided) to the specified sector. Thereafter, data (signals) are read via the head 15 from the specified sector. The read signals are amplified by a preamplifier (not shown) and then inputted to the read demodulator of the read channel 104. The read data are demodulated in the read demodulator by partial response maximum likelihood (PRML) or the like and inputted to the ECC correction unit 86 in the hard disk controller 102.

Subsequently, in Step S14, the ECC correction unit 86 calculates an ECC syndrome from the read data. Thereafter, in Step S16, the ECC correction unit 86 detects the position of any error data and a numerical value of the error data included in the ECC syndrome and corrects the error data.

Next, in Step S18, the ECC correction unit 86 determines whether or not all errors in the read data have been corrected in Step S16. If the read data have included no errors or all errors have been corrected, then a positive determination is made in Step S18. Therefore, if it is determined that all errors in the read data have been corrected, then all of the operations shown in FIG. 4 are terminated. If it is determined that all errors in the read data have not been corrected, then Step S20 proceeds.

In Step S20, the data verification circuit 115 performs verification of the dummy data. Specifically, the data verification circuit 115 compares the dummy data included in the read data (dummy data recorded to an area of 3.5 Kbytes in FIG. 3) with the predetermined dummy data (i.e., source data) for verification. Any difference between the dummy data included in the read data and the predetermined dummy data represents that the read data include an error. Therefore, if the data verification circuit 115 detects any difference between the dummy data and the source data through the verification, the data verification circuit 115 transmits information on the location of the error to the verification result record circuit 117. Then the verification result record circuit 117 records the information on the location of the error.

Then, in Step S22, the ECC correction unit 86 sets an erasure code at the location of the error based on the information recorded in the verification result record circuit 117.

Subsequently, in Step S24, the ECC correction unit 86 performs an ECC correction on all data elements of the data in consideration of the error location at which the erasure code has been set. In this case, an ECC correction of the portion at which the erasure code has been set can be performed with a half amount of processing capability. Therefore, a throughput of the ECC correction can be expected to be improved. In other words, the number of correctable errors can be increased.

Specifically, the following relationship should be maintained:

A+(E/2)≦K (1)

where A is the number of errors having an unknown location, E is the number of errors having a known location, and K is the number of correctable errors.

The above relationship can be converted into the following relationship:

(T−E)+(E/2)≦K (2)

T−E/2≦K (3)

where T is the total number of errors (=A+E).

From the above relationship (3), it can be seen that the total number of correctable errors (T) can be increased by increasing the number of errors having a known location (E). Thus, with the verification of the dummy data (Step S20), the setting of an erasure code at the error location (Step S22), and the ECC correction using the erasure code (Step S24) as described above, an error correction can be performed more reliably as compared to a simple ECC correction.

In Step S26, the ECC correction unit 86 determines whether or not all errors have been corrected in the entire read data including the dummy data subjected to the aforementioned error correction. If the actual data (512 bytes) include no errors, a positive determination is made in Step S26. Therefore, if it is determined that all errors have been corrected, then no further error correction is needed. Accordingly, all of the operations shown in FIG. 4 are terminated. On the other hand, if the actual data (512 bytes) include any error, a negative determination is made in Step S26. Therefore, an error correction subroutine for the actual data is then executed in Step S28. When this subroutine is to be executed, a parameter n indicating the number of reading operations (read count) is set to an initial value of one, and a parameter m indicating the number of retrials is set to an initial value of one.

The subroutine of Step S28 is performed as shown in FIG. 5. First, in Step S40, the MPU 84 reads the actual data (512 bytes). The reading operation of the actual data is performed in the same manner as described in Step S12. Next, in Steps S42 and S44, the ECC correction unit 86 performs calculation of an ECC syndrome and ECC correction in the same manner as described in Steps S14 and S16. Then, in Step S46, the ECC correction unit 86 determines whether or not all errors have been corrected. If it is determined that all errors have not been corrected, then the ECC correction unit 86 determines in Step S48 whether or not the number of reading operations (read count) n exceeds a predetermined value N. If it is determined that the read count does not exceed the predetermined value, then Step S50 proceeds so that the ECC correction unit 86 increments n by one. Thereafter, the process returns to Step S40.

Subsequently, the ECC correction unit 86 repeats Steps S40-S50. If the error correction has been completed, a positive determination is made in Step S46. Therefore, if it is determined in Step S46 that all errors have been corrected, then all of the operations in the subroutine shown in FIG. 5 and all of the operations shown in FIG. 4 are terminated. If it is determined in Step S48 that the read count exceeds the predetermined value, then Step S52 proceeds.

Next, in Step S52, the ECC correction unit 86 estimates an erasure code. In Step S54, the ECC correction unit 86 performs an ECC correction in consideration of the estimated erasure code. In Step 56, the ECC correction unit 86 determines whether or not all errors have been corrected in Step S54. If it is determined that all errors have not been corrected in Step S54, then the ECC correction unit 86 determines in Step S58 whether or not the number of retrials (retrial count) m exceeds M. If it is determined that the retrial count m does not exceed M, then Step S60 proceeds so that the ECC correction unit 86 increments m by one. Thereafter, the process returns to Step S52.

Subsequently, the ECC correction unit 86 repeats Steps S52-S60. If the error correction has been completed, a positive determination is made in Step S56. Therefore, if it is determined in Step 56 during the repetition that all errors have been corrected, then all of the operations in the subroutine shown in FIG. 5 and all of the operations shown in FIG. 4 are terminated. If it is determined in Step S58 that the number of retrials (retrial count) m exceeds M, then Step S62 proceeds. This situation means that all errors have not successfully been corrected even though the retrial count m exceeds M. Therefore, it is determined in Step S62 that the error correction (recovery) has failed, and all of the operations in the subroutine shown in FIG. 5 and all of the operations shown in FIG. 4 are terminated.

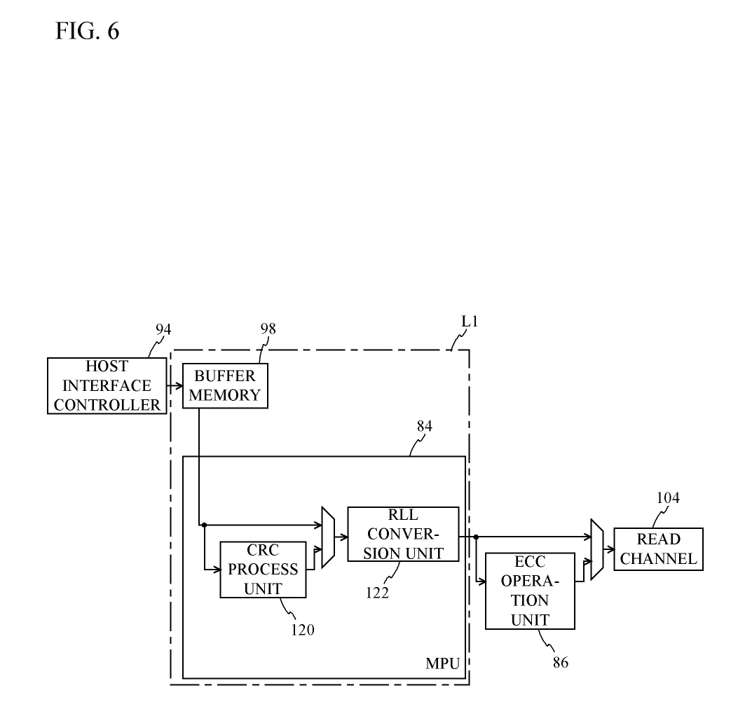

Meanwhile, in the present embodiment, the actual data are transferred and processed from the host interface controller 94 to the read channel 104 as shown in FIG. 6. Specifically, the actual data inputted from the host 82 (see FIG. 2) are transferred from the host interface controller 94 to the buffer memory 98 and stored in the buffer memory 98. In the buffer memory 98, dummy data are appended to the actual data. Then the data are transmitted to the MPU 84. The MPU 84 has a CRC process unit 120 and an RLL conversion unit 122. In the CRC process unit 120 of the MPU 84, a cyclic algorithm (generating polynomial) is applied to the actual data to generate redundant data (CRC code). The redundant data are added to the actual data and then transmitted to the RLL conversion unit 122. In the RLL conversion unit 122, an RLL conversion (high rate run length limited encode (HRRL)) is performed on the data (at least on the actual data). The RLL conversion is used to generate waves at continuous intervals to prevent waves of the data from being linear. For example, when the data include the same value (e.g., zero) in succession, the RLL conversion modifies the data to prevent waves of the data from being linear. Furthermore, the ECC correction unit 86 calculates an ECC syndrome by using the data subjected to the RLL conversion. The calculated ECC syndrome is added to the data subjected to the RLL conversion and transmitted to the read channel 104.

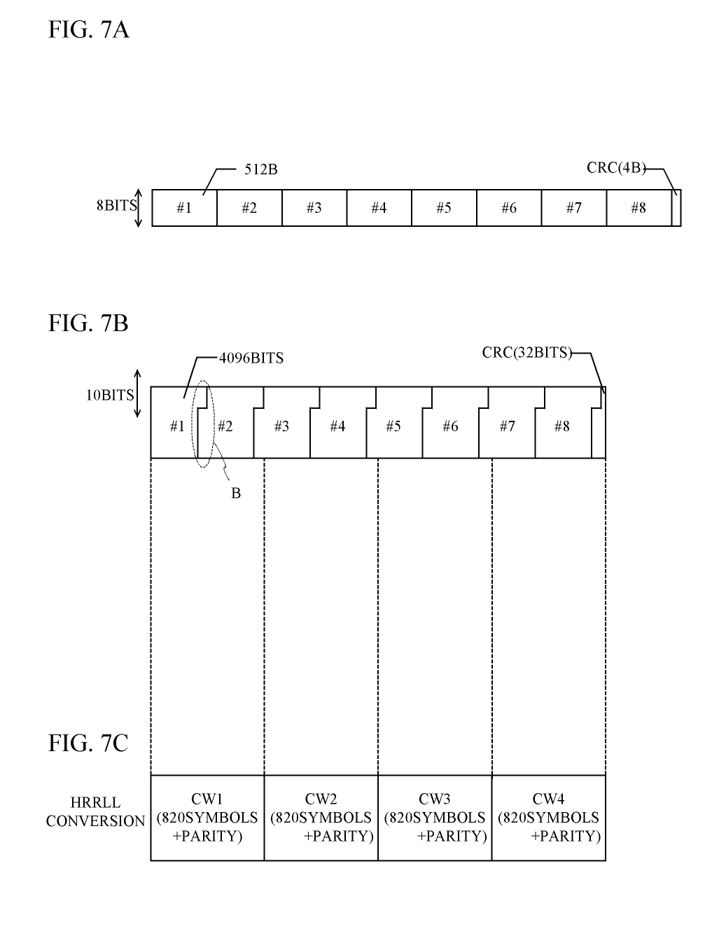

The RLL conversion is performed as shown in FIG. 7A. The data are inputted to the RLL conversion unit 122 by the byte (1 byte=8 bits). The inputted data are converted into the units of Symbol as shown in FIG. 7B (1 Symbol=10 bits). The data shown in FIG. 7B are rearranged into several divisions in one sector as shown in FIG. 7C. One division is referred to as a code word (CW). The code word is used as the unit of the RLL conversion. In the example shown in FIG. 7A, a plurality of sets of 512-byte data are used as dummy data. In this example, as shown in FIG. 7C, one sector is divided into four code words CW1-CW4, each of which has a data capacity of (820 Symbols+parity).

In view of the format efficiency, the data conversion (the conversion from FIG. 7A to FIG. 7B) is usually performed such that no gaps are produced between continuous sets of data. In this case, as seen in a portion B encircled in FIG. 7B by a dashed line, data #1 and data #2 are mixed in one symbol.

Furthermore, as shown in FIGS. 7A to 7C, data # 1, data #2, and a portion of data #3 are coded in CW1. The rest of data #3, data #4, and a portion of data #5 are coded in CW2. The rest of data #5, data #6, and a portion of data #7 are coded in CW3. The rest of data #7, data #8, and a CRC portion are coded in CW4. Thus, data #2 and the portion of data #3 (the leading 8 bits) are included in CW1. Therefore, assuming that only data #1 are actual data, data #2 and #3 (dummy data) cannot be analyzed as dummy data in the verification with the source data and in the error correction.

Accordingly, in the present embodiment, the following two methods can be employed for the RLL conversion.

### First Method

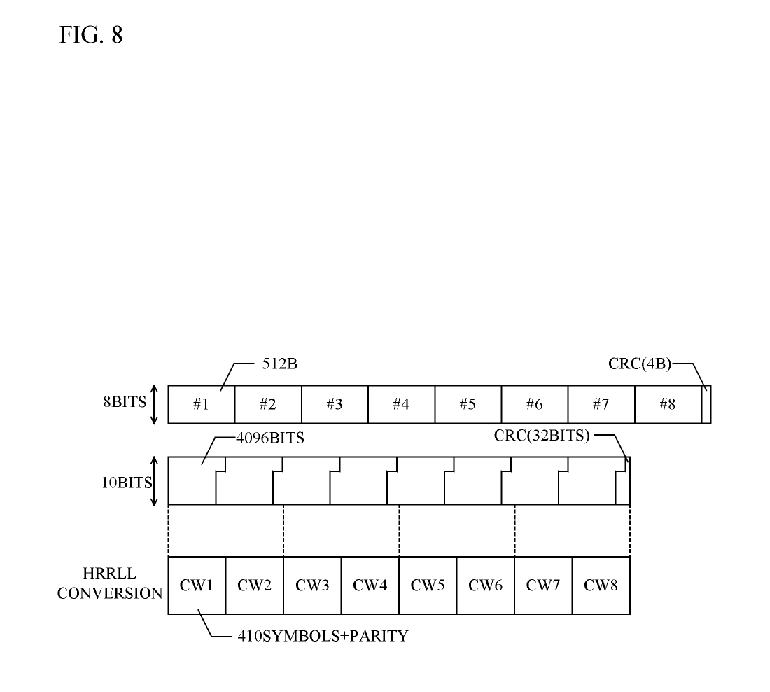

For example, as shown in FIG. 8, the code words are configured so as to have a length shorter than that in FIG. 7C. In the example shown in FIG. 8, each code word has a length of (410 Symbols+parity). With such a configuration, even if only data #1 are actual data, the dummy data including data #3 can be analyzed for the verification with the source data and for the error correction. Thus, an analyzable range can be increased as compared to the case shown in FIGS. 7A to 7C.

Whether an analyzable range is increased also depends upon the quantity of actual data included in one sector. For example, it depends upon whether only data #1 are actual data or whether data #1 and #2 are actual data. Therefore, it is preferable that the length of the code words be determined in consideration of the quantity of actual data so as to increase an analyzable range as much as possible.

### Second Method

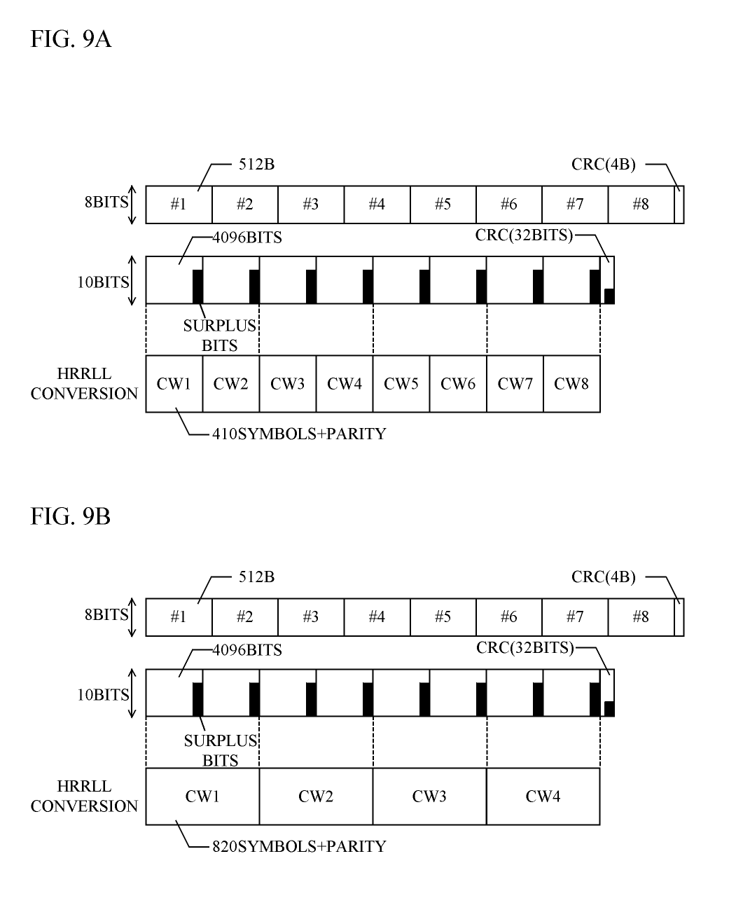

This method differs from the aforementioned methods in which no gaps are produced between continuous sets of data as shown in FIG. 7B. In this method, as shown in FIG. 9A, surplus bits (4 bits) are provided when the byte-unit data are converted into the symbol-unit data. With such a configuration, the length of data (4,100 bits) including one set of data (4,096 bits) and surplus bits (4 bits) can be made equal to the length of a code word (410 Symbols). In this case, no sectors (data) are divided into two code words. Therefore, an analyzable range can be increased.

This method is not limited to the example shown in FIG. 9A. As shown in FIG. 9B, the length of one set of data including actual data (or dummy data) and surplus bits may be set to be ½ of the length of the code words. Alternatively, the length of one set of data including actual data (or dummy data) and surplus bits may be set to be 1/s of the length of the code words where s is an integer.

In the above examples, all data elements of dummy data (source data) are zero. In such a case, a portion having zero in succession may be subjected to the RLL conversion, making it difficult to readily perform verification with the source data.

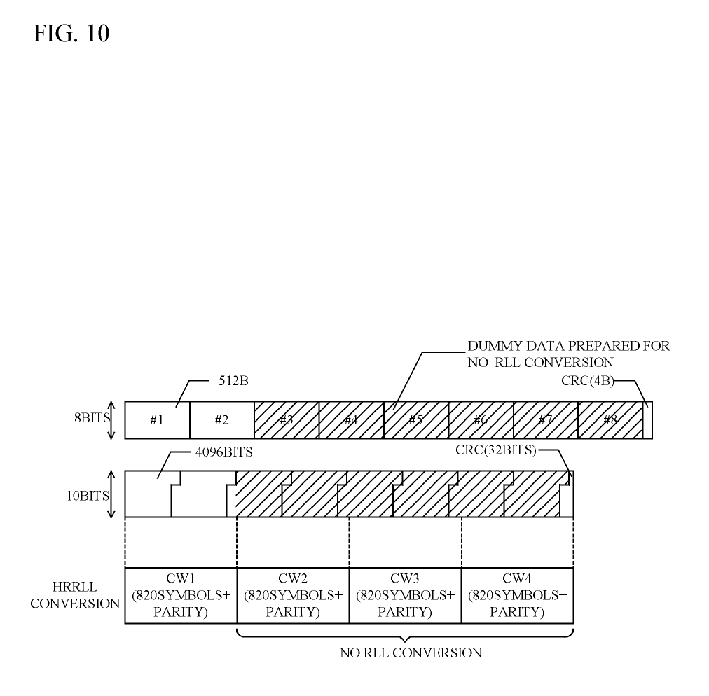

Accordingly, in the present embodiment, the source data may be configured so as to have a pattern in which a predetermined number of bits do not have the same value (e.g., zero) in succession so as to prevent an RLL conversion. In FIG. 10, shaded sets of dummy data are configured such that an RLL conversion is not performed on those sets. With such a configuration, the dummy data can readily be verified with the source data.

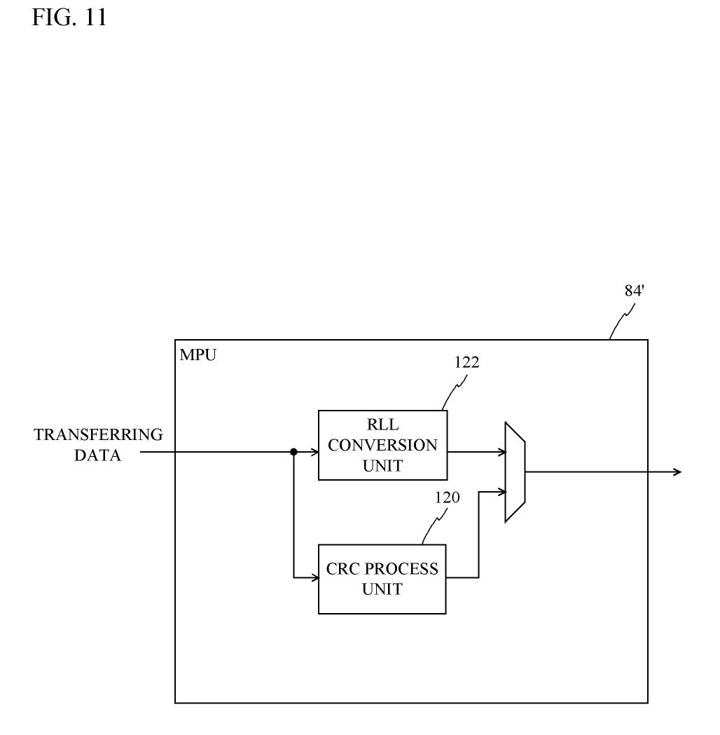

This operation can be implemented by replacing the MPU 84 of FIG. 6 with an MPU 84′ shown in FIG. 11. Specifically, the RLL conversion unit 122 is arranged in parallel with the CRC process unit 120. Only actual data are inputted to the RLL conversion unit 122. Data in which dummy data is added to the actual data are inputted to the CRC process unit 120. The MPU 84′ outputs data including actual data that have been subjected to an RLL conversion, dummy data that have not been subjected to an RLL conversion, and a CRC portion.

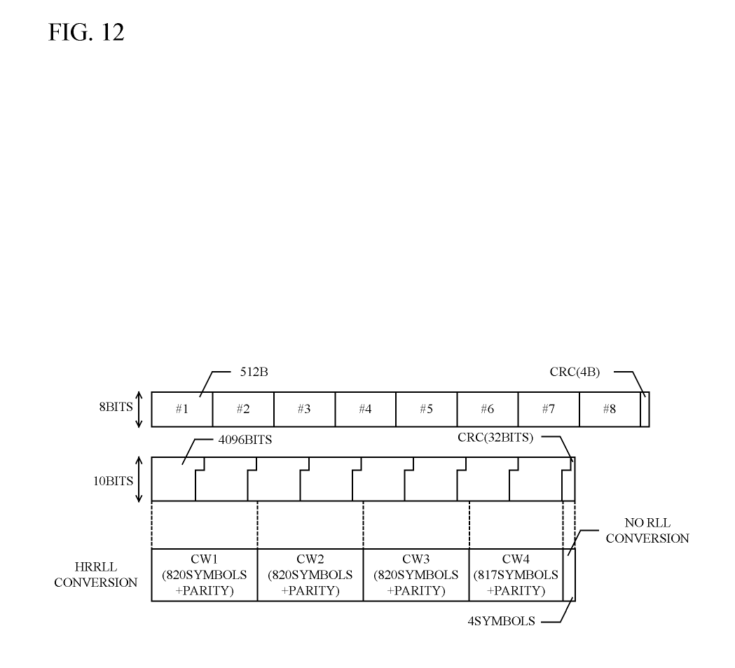

In the present embodiment, as shown in FIG. 7C, a CRC portion is added to an end of data. In this case, a code word (CW4) including a CRC portion cannot be analyzed in fact. Accordingly, for example, a CRC portion may be separated from CW1-CW4 as shown in FIG. 12 such that the CRC portion is not subjected to an RLL conversion. With such a configuration, dummy data included in CW4 can be analyzed.

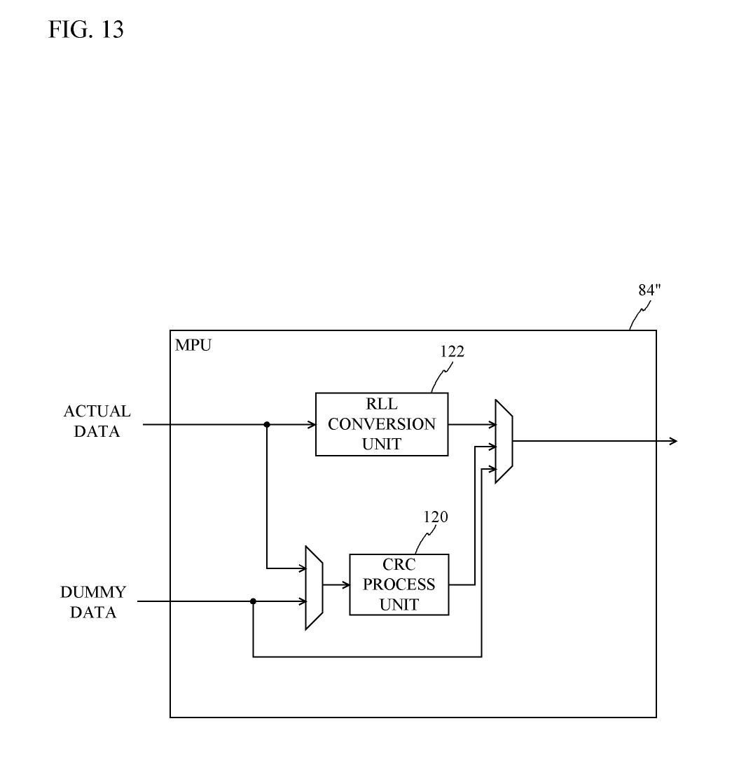

This operation (the operation shown in FIG. 12) can be implemented by replacing the MPU 84 of FIG. 6 with an MPU 84″ shown in FIG. 13. Specifically, the RLL conversion unit 122 is arranged in parallel with the CRC process unit 120. Actual data (transferring data) to which dummy data are added are inputted to the RLL conversion unit 122. Those transferring data are also inputted to the CRC process unit 120. The MPU 84″ outputs data including transferring data that have been subjected to an RLL conversion and a CRC portion that has not been subjected to an RLL conversion.

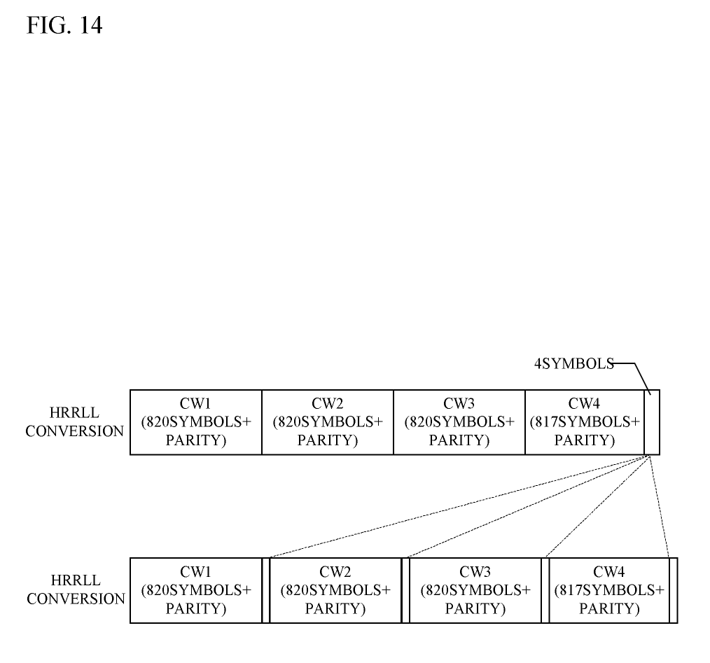

For example, as shown in FIG. 14, the CRC portion may be inserted to between CW1 and CW2, between CW2 and CW3, between CW3 and CW4, and after CW4, respectively, subsequently to the operation shown in FIG. 12. If the CRC portions are inserted between code words without an RLL conversion as shown in FIG. 14, then the above restriction against successive zeros is not applied to the inserted CRC portions, so that successive zeros may be formed instantaneously. However, those successive zeros are not problematic in processing data as long as the restriction against successive zeros is maintained in the next code word. Additionally, because the CRC portion has a data pattern of randomness, there may be a low probability that successive zeros are formed with a CRC portion. Thus, no risk is expected by the insertion CRC portions between code words.

The present embodiment is not limited to the case in which the operation shown in FIG. 12 is performed. For example, a small-scale RLL conversion (low rate run length limited encode (LRRL)) may be performed on the CRC portions.

As described above, according to the present embodiment, dummy data based on predetermined source data are recorded to an area of a sector other than an area to which actual data inputted from the host 82 are recorded via the hard disk controller 102, the read channel 104, the head IC 52, the head 15, and the like. When the actual data are to be read, the ECC correction unit 86 verifies the dummy data recorded to the sector to which the actual data have been recorded with the source data. The ECC correction unit 86 performs an ECC correction on the dummy data in consideration of the verification results. Therefore, the location of an error in the dummy data can be detected simply by verifying the dummy data with the source data. Thus, the ECC correction unit 86 can complete an ECC correction on the dummy data readily in a short period of time by using the verification results.

Furthermore, in the present embodiment, the dummy data are verified with the source data so that the location of an error is specified by a difference between the dummy data and the source data. The ECC correction is performed on the dummy data by using the information on the location of the error (by setting an erasure code). If the location of an error is thus specified (by setting an erasure code), then an ECC correction can be performed with a half amount of processing capability as compared to a case in which the location of an error is not specified. Accordingly, a throughput of an error correction in the HDD 100 can be improved, and the number of correctable errors can be increased.

Moreover, in the present embodiment, before the verification of the dummy data with the source data, an ECC correction is performed on the entire data in a sector to which the actual data to be read have been recorded. Based on those correction results, it is determined whether or not to perform the verification of the dummy data with the source data. Thus, the verification of the dummy data with the source data is not performed if the entire data in a sector include no errors or if all errors have been corrected by one ECC correction. Accordingly, an unnecessary verification can be avoided. Therefore, an error correction can be performed efficiently.

In the present embodiment, if it is determined that all errors have not been corrected in an ECC correction after setting an erasure code, then an error correction is performed on the actual data. Therefore, an error correction can efficiently be performed on the actual data.

Furthermore, the HDD 100 in the present embodiment includes the magnetic disk 12 and an error correction circuit (the control board 90) capable of completing an ECC correction on dummy data readily in a short period of time. Therefore, an ECC correction of the entire data including the actual data can be completed readily in a short period of time. Accordingly, the accuracy and speed of reading data from the magnetic disk 12 can be improved, and the processing capability required for reading data can be reduced.

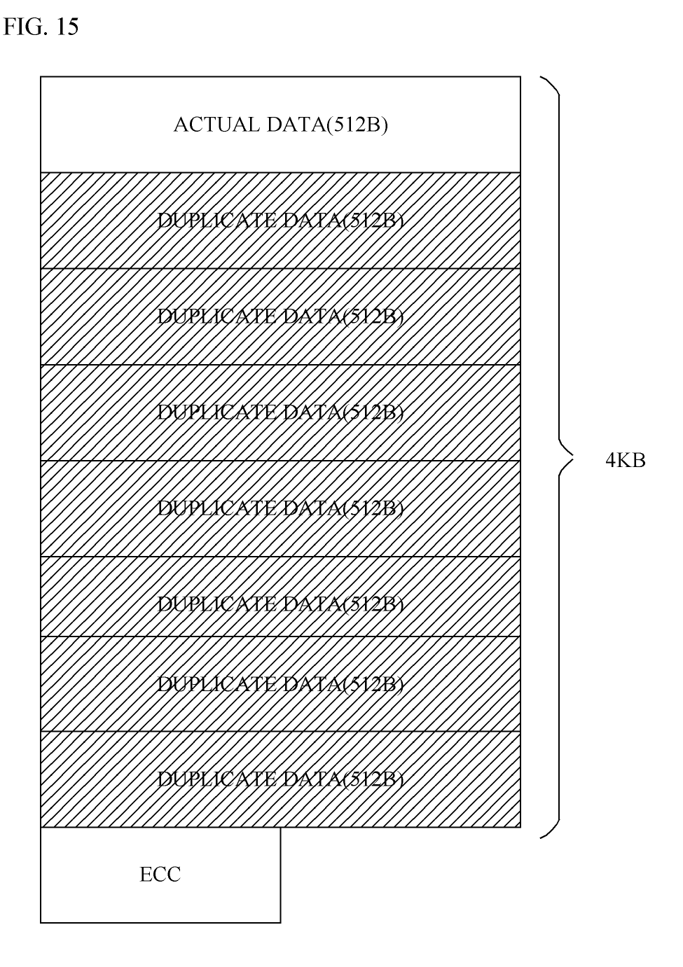

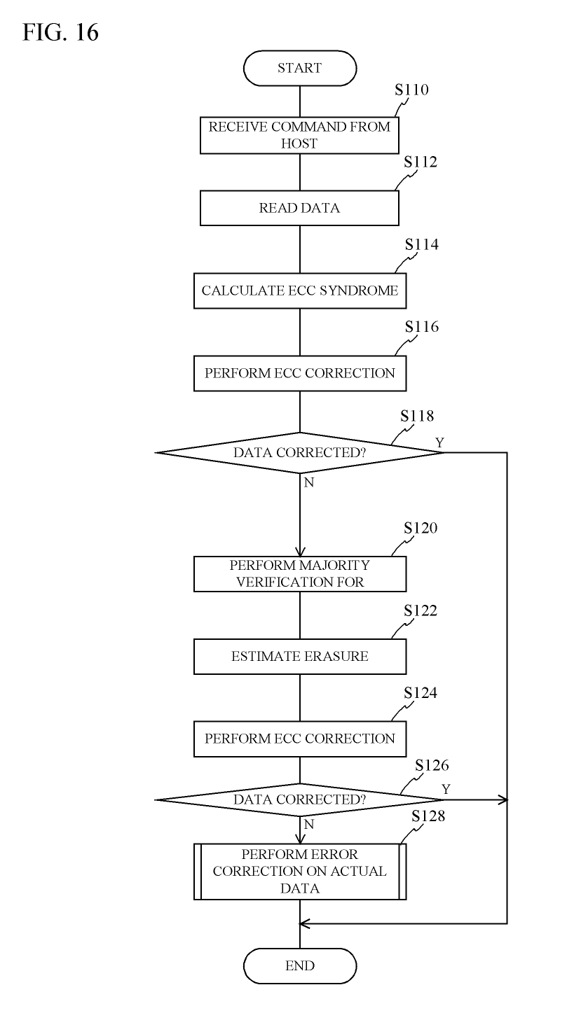

In the above embodiment, the dummy data are data having a pattern different from the actual data (e.g., data in which all data elements are zero). However, the present invention is not limited to this example. For example, as shown in FIG. 15, duplicate data of the actual data may be used as additional data written to a sector in additional to the actual data. When 512-byte actual data are recorded to a 4-Kbyte sector, seven sets of duplicate data may be recorded to the remaining area. In this case, an error correction of the additional data (duplicate data) can be performed in a sequence shown in FIG. 16.

Specifically, the same operations as in Steps S10-S18 of the sequence shown in FIG. 4 are performed in Steps S110-S118 of FIG. 16. In FIG. 16, a majority verification is performed in Step S120 instead of the dummy data verification in Step S20 of FIG. 4. The majority verification is performed in the following manner. The sets of duplicate data are compared with each other. If any difference is found between at least one set of duplicate data and other sets of duplicate data by the comparison, then data elements at the location of each set in which the difference has been found are aggregated so as to determine by a majority which sets of duplicate data do not include an error. For example, if the comparison results of seven sets of duplicate data show that data elements at a specific location of two sets of duplicate data are one while data elements at the same location of other sets of duplicate data are zero, then the data sets with elements having a value of one, the count of which is less than that of the other data sets, are determined to include an error at the specific location.

As with the above embodiment, the location of an error can be specified by performing the aforementioned majority verification in each sector. In Step S122, an erasure code is set at the location of the error which has been specified in Step S120. The subsequent operations in Steps S124-S128 are performed in the same manner as in Steps S24-S28 in the above embodiment (FIGS. 4 and 5).

As described above, in this example shown in FIGS. 15 and 16, since duplicate data of actual data are used as dummy data, predetermined data, which are required in the above embodiment, need not be prepared separately for source data. Furthermore, because all sets of duplicate data are converted in the same manner by an RLL conversion, verification can readily be performed between those sets of duplicate data.

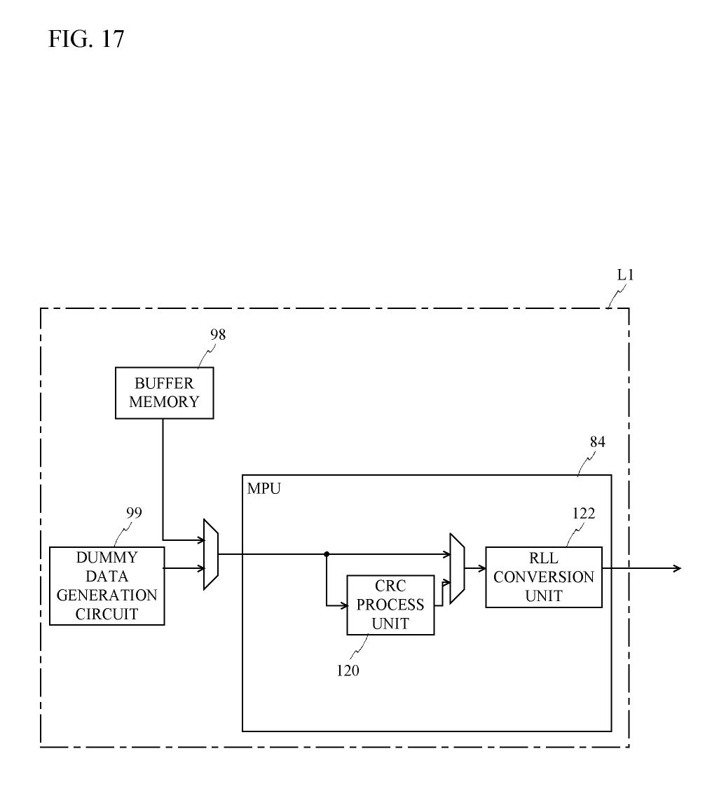

In the example shown in FIG. 6, the dummy data are added to the actual data in the buffer memory 98. The present invention is not limited to that example. For example, the components within the area L1 surrounded by a chain line in FIG. 6 may be replaced with components shown in FIG. 17. Specifically, a dummy data generation circuit 99 operable to generate dummy data may be provided separately from the buffer memory 98. Dummy data may be generated by the dummy data generation circuit 99 and added to actual data outputted from the buffer memory 98.

In the above embodiment, an erasure code is set based on the verification of dummy data (see Steps S20 and S22 of FIG. 4), and then an ECC correction is performed. However, the present invention is not limited to this example. For example, if an error is found by the verification of dummy data, that error may be corrected directly, and then an ECC syndrome may be recalculated. In such a case, a ratio of error correction (ratio of recovery) can be improved.

The aforementioned embodiments have been described as preferred embodiments of the present invention. The present invention is not limited to the illustrated embodiments and examples. It would be apparent to those skilled in the art that many modifications and variations may be made therein without departing from the spirit and scope of the present invention.

What is claimed is:

1. An error correction method comprising:
writing actual data having a first length together with additional data produced from source data to a magnetic disk having sectors having a read/write unit of a second length that is longer than the first length;
specifying one of the sectors to which actual data to be read have been written;
reading actual data and additional data from the specified sector;
verifying the read additional data with the source data; and
performing a first error correction on the read additional data based on a result of the verification.

2. The error correction method as recited in claim 1, wherein the verification of the read additional data comprises comparing the read additional data with the source data to find a difference between the read additional data and the source data, and
the first error correction of the read additional data comprises performing an error correction on the read additional data based on information on the difference between the read additional data and the source data.

3. The error correction method as recited in claim 1, further comprising:
performing a second error correction on entire data of the specified sector before the verification of the read additional data; and
determining whether or not to perform the verification of the read additional data based on a result of the second error correction of the entire data.

4. The error correction method as recited in claim 1, further comprising performing a third error correction on the read actual data based on a result of the first error correction of the read additional data.

5. The error correction method as recited in claim 1, wherein the writing operation of the actual data comprises:
dividing data including actual data and additional data to be written to one sector of the magnetic disk into a plurality of code words, and
performing a run length limited encode on at least a code word including the actual data to be written.

6. The error correction method as recited in claim 5, wherein the writing operation of the actual data further comprises:
preparing a plurality of sets of additional data to be written to the sector of the magnetic disk, and
adding one or more surplus bits to the actual data to be written and to each set of additional data to be written so that a length of data including the actual data and the surplus bits and a length of data including each set of additional data and the surplus bits are equal to 1/s of the code word where s is an integer.

7. The error correction method as recited in claim 1, wherein the writing operation of the actual data comprises:
dividing data including actual data and additional data to be written to one sector of the magnetic disk into a plurality of code words, and
performing a run length limited encode on only a code word including the actual data to be written,
wherein the source data comprises data produced within a range of the run length limited encode.

8. The error correction method as recited in claim 1, wherein the writing operation of the actual data comprises:
dividing data including actual data and additional data to be written to one sector of the magnetic disk into a plurality of code words,
generating an error detecting code from the actual data and the additional data, and
performing a run length limited encode on data other than the error detecting code.

9. The error correction method as recited in claim 1, wherein the source data comprises predetermined data.

10. The error correction method as recited in claim 9, wherein the additional data comprises a plurality of sets of dummy data produced from the predetermined data.

11. The error correction method as recited in claim 1, wherein the source data comprises the actual data.

12. The error correction method as recited in claim 11, wherein the additional data comprises a plurality of sets of duplicate data of the actual data.

13. The error correction method as recited in claim 12, wherein the verification of the read additional data comprises:
comparing the plurality of sets of duplicate data as the read additional data with each other to find a difference between the plurality of sets of duplicate data,
aggregating data elements in which the difference is found in the plurality of sets of duplicate data, and
determining which set of duplicate data includes an error based on a result of the aggregation.

14. An error correction circuit comprising:
a writing unit operable to write actual data having a first length together with additional data produced from source data to a magnetic disk having sectors having a read/write unit of a second length that is longer than the first length;
a reading unit operable to specify one of the sectors to which actual data to be read have been written and to read actual data and additional data from the specified sector;
a verification unit operable to verify the additional data read by the reading unit with the source data; and
a correction unit operable to perform a first error correction on the additional data read by the reading unit based on a result obtained by the verification unit.

15. A magnetic disk device comprising:
a magnetic disk;
a writing unit operable to write actual data having a first length together with additional data produced from source data to the magnetic disk, the magnetic disk having sectors having a read/write unit of a second length that is longer than the first length;
a reading unit operable to specify one of the sectors to which actual data to be read have been written and to read actual data and additional data from the specified sector;
a verification unit operable to verify the additional data read by the reading unit with the source data; and
a correction unit operable to perform a first error correction on the additional data read by the reading unit based on a result obtained by the verification unit.
